(19) United States
(12) Patent Application Publication
(10) Pub. No.: US 2020/0043969 A1
(43) Pub. Date: Feb. 6, 2020

(54) SEMICONDUCTOR DEVICE AND METHOD OF MANUFACTURING THE SAME

(71) Applicant: HUAIAN IMAGING DEVICE MANUFACTURER CORPORATION, HUAIAN (CN)

(72) Inventors: Bin GUAN, HUAIAN (CN); Kishou KANEKO, HUAIAN (CN); Shijie CHEN, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/394,443

(22) Filed: Apr. 25, 2019

(30) Foreign Application Priority Data
Aug. 3, 2018 (CN) 201810874046.4

(51) Int. Cl. H01L 27/146

(52) U.S. Cl. CPC H01L 27/14636; H01L 27/1469; H01L 27/14634

(57) ABSTRACT

A method of manufacturing a semiconductor device comprises: providing a stacked structure comprising a first wafer that includes a first substrate, a first insulating layer and a first electrical connector and a second wafer that includes a second substrate, a second insulating layer and a second electrical connector; forming a first portion of a TSV which overlaps at least part of the first and second electrical connectors and exposes a part of a surface of the first insulating layer; forming an insulating film that at least covers side surfaces and a bottom surface of the first portion; forming a first conductive barrier film retained on the side surfaces of the first portion; forming a second portion of the TSV that exposes the first and second electrical connectors; forming a conductive plug in the first and second portions, to interconnect the first and second electrical connectors.

### CROSS-REFERENCE TO RELATED APPLICATIONS

This application claims priority to Chinese Patent Application No. 201810874046.4, filed on Aug. 3, 2018, which is hereby incorporated by reference in its entirety.

### TECHNICAL FIELD

The present disclosure relates generally to the field of semiconductor technology, and more particularly, to a semiconductor device and a method of manufacturing the same in the field of image sensor.

### BACKGROUND

Many modern electronic apparatuses relate to electronic devices using image sensors, for example SLR cameras, ordinary digital cameras, video cameras, mobile phones, automotive electronics, and so on. Accordingly, there is always a need in the art for image sensors with improved image quality and semiconductor devices including such image sensors.

### SUMMARY

One of aims of the present disclosure is to provide a new method of manufacturing a semiconductor device and the semiconductor device manufactured by the method.

One aspect of this disclosure is to provide a method of manufacturing a semiconductor device, comprising the steps of: providing a stacked structure, wherein the stacked structure may comprise: a first wafer that may include a first substrate and a first insulating layer over the first substrate and a first electrical connector in the first insulating layer; a second wafer that may include a second substrate and a second insulating layer over the second substrate and a second electrical connector in the second insulating layer, wherein the first wafer is bonded to the second wafer in such a way that the first insulating layer faces the second insulating layer; forming a first portion of a silicon through hole TSV from a side of the first substrate opposite to the first insulating layer, wherein the first portion of the TSV overlaps at least part of the first electrical connector and at least part of the second electrical connector and penetrates through the first substrate and exposes a part of a surface of the first insulating layer; forming an insulating film that may at least cover side surfaces and a bottom surface of the first portion of the TSV; forming a first conductive barrier film over the insulating film; removing a part of the first conductive barrier film to retain the first conductive barrier film on the side surfaces of the first portion of the TSV; removing the insulating film at the bottom surface of the first portion of the TSV and a part of the first insulating layer and the second insulating layer below it, thereby forming a second portion of the TSV that exposes the at least part of the first electrical connector and the at least part of the second electrical connector; forming a conductive plug that fills the first portion and the second portion of the TSV, to interconnect the first electrical connector with the second electrical connector.

Another aspect of this disclosure is to provide a semiconductor device that may comprise: a first wafer that may include a first substrate and a first insulating layer over the first substrate and a first electrical connector in the first insulating layer; a second wafer that may include a second substrate and a second insulating layer over the second substrate and a second electrical connector in the second insulating layer, wherein the first wafer is bonded to the second wafer in such a way that the first insulating layer faces the second insulating layer; a silicon through hole TSV comprising a first portion and a second portion, wherein the first portion of the TSV overlaps at least part of the first electrical connector and at least part of the second electrical connector and penetrates through the first substrate and exposes a part of a surface of the first insulating layer; wherein the second portion is in part of the first insulating layer and the second insulating layer to expose the at least part of the first electrical connector and the at least part of the second electrical connector; a conductive barrier film that may cover side surfaces and a bottom surface of the TSV, wherein a thickness of the conductive barrier film in the first portion of the TSV in a direction perpendicular to the side surfaces may be greater than a thickness of the conductive barrier film in the second portion of the TSV in the direction perpendicular to the side surfaces; a conductive plug that fills the TSV covered by the conductive barrier film, and interconnects the first electrical connector with the second electrical connector.

A further aspect of this disclosure is to provide a semiconductor device that may comprise: a first wafer that may include a first substrate and a first insulating layer over the first substrate and a first electrical connector in the first insulating layer; a second wafer that may include a second substrate and a second insulating layer over the second substrate and a second electrical connector in the second insulating layer, wherein the first wafer is bonded to the second wafer in such a way that the first insulating layer faces the second insulating layer; a silicon through hole TSV comprising a first portion and a second portion, wherein the first portion of the TSV overlaps at least part of the first electrical connector and at least part of the second electrical connector and penetrates through the first substrate and exposes a part of a surface of the first insulating layer; wherein the second portion is in part of the first insulating layer and the second insulating layer to expose the at least part of the first electrical connector and the at least part of the second electrical connector; a conductive barrier film that may cover side surfaces and a bottom surface of the TSV and may comprise one or more conductive barrier layers, wherein the number of the conductive barrier layers of the conductive barrier film in the first portion of the TSV may be more than the number of the conductive barrier layers of the conductive barrier film in the second portion of the TSV; a conductive plug that fills the TSV covered by the conductive barrier film and interconnects the first electrical connector with the second electrical connector.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according to the following detailed description with reference of the accompanying drawings.

FIG. 1 illustrates an illustrative circuit schematic diagram of a typical CMOS image sensor.

FIG. 2 illustrates an illustrative sectional view of a part of a typical stack type BSI image sensor.

FIG. 3 illustrates a flowchart of steps of manufacturing a semiconductor device according to one or more exemplary embodiments of this disclosure.

FIG. 4 illustrates a flowchart of steps of manufacturing a semiconductor device according to one or more exemplary embodiments of this disclosure.

FIGS. 5-11 are sectional views illustrating main processing steps of a process of manufacturing a semiconductor device according to one or more exemplary embodiments of this disclosure.

FIGS. 12-15 are sectional views illustrating main processing steps of a process of manufacturing a semiconductor device according to one or more exemplary embodiments of this disclosure.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the elements and steps, the numerical expressions, and numerical values set forth in these embodiments do not limit the scope of the present disclosure unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific elements.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

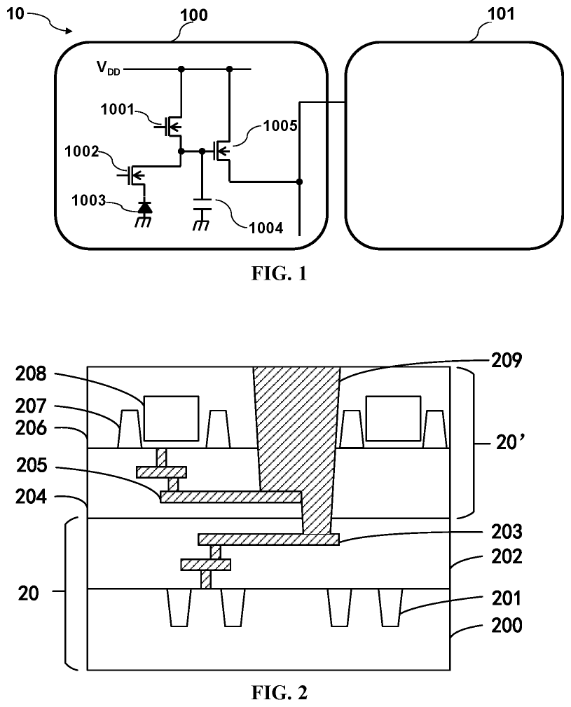

FIG. 1 illustrates an illustrative circuit schematic diagram of a typical CMOS image sensor 10. The CMOS image sensor 10 may include a pixel region 100 and a logic region 101. In the operation of the CMOS image sensor 10, light is incident on a photodiode 1003. The photodiode 1003 converts the light into charges proportional to the intensity of the incident light. A transfer transistor 1002 turns on or off the transfer of the charges from the photodiode 1003 to a floating diffusion portion 1004 according to a drive signal provided by the logic region, for example. A reset transistor 1001 determines whether to discharge the charges accumulated in the floating diffusion portion 1004 according to a drive signal provided by the logic region 101, for example. An amplification transistor 1005 amplifies a voltage corresponding to the charges accumulated in the floating diffusion portion 1004.

The logic region 101 of the CMOS image sensor 10 may include, for example, signal amplifiers, column drivers, row selection units, timing control logic, AD converters, data bus output structures, control interfaces, address decoders and analog/digital conversion (ADC) circuits, and other processing circuits, e.g., processing circuits for automatic exposure control, non-uniform compensation, white balance treatment, black level control, gamma correction. The processing circuit in the logic region 101 of the CMOS image sensor 10 is used for further processing the signal obtained from the amplification transistor 1005. In addition, those skilled in the art would appreciate that, the illustrative circuit schematic diagram of the CMOS image sensor 10 shown in FIG. 1 is shown only for example and does not limit the present disclosure. The CMOS image sensor in the disclosure can be arranged differently from the arrangement in FIG. 1.

In general, in the traditional front side illumination (“FSI”) CMOS image sensor (where light is incident from the metal wiring side to the photodiode) and the back side illumination (“BSI”) CMOS image sensor (where the light is incident from a side opposite to the metal wiring side to the photodiode), the pixel region 100 and the logic region 101 are formed in the same substrate, which causes a part of the substrate area to be occupied by the processing circuit in the logic region, resulting in a decrease in an area occupied by the pixel region.

In stack type image sensor developed in recent years, photodiodes are formed in a pixel wafer, while the signal processing circuits are formed in a logic wafer different from the pixel wafer. The logic wafer can also include other elements, such as capacitors, resistors, memory units, analog devices, filters, transceivers, and so on. By bonding the two wafers to each other and forming a conductive plug connecting top metal connectors in the pixel wafer and the logic wafer, stacked metal parts in the two wafers can be interconnected to form electrically communicated paths of the elements and circuits in the two wafers. Therefore, in such stack type image sensor, it is possible to form a large number of pixels on a smaller sensor chip size. In addition, since the pixels and the processing circuits in the sensor are separate and independent of each other, the pixel portion can be optimized for higher image quality, and the circuit portion can also be optimized for high performance.

FIG. 2 illustrates an illustrative sectional view of a part of a typical stack type BSI image sensor.

As shown in FIG. 2, the stack type BSI image sensor may include a stacked structure of a logic wafer 20 and a pixel wafer 20′. By forming a conductive plug 209, a top metal part 203 formed in an insulating layer 202 of the logic wafer 20 can be interconnected with a top metal part 205 formed in an insulating layer 204 of the pixel wafer 20′, such that the elements or circuits in the substrate 200 of the logic wafer 20 may be electrically coupled with photodiodes 208, or pixel circuits such as a transfer transistor and an amplification transistor in the substrate 206 of the pixel wafer 20′. In one embodiment, for example, the elements or circuits in the substrate 200 are separated by isolation trenches 201. In one embodiment, for example, the photodiodes 208 in the substrate 206 are separated by isolation trenches 207.

As can be learned from the above, when forming the stack type BSI image sensor structure, after the pixel wafer 20′ and the logic wafer 20 are bonded to each other and the back side of the pixel wafer 20′ is thinned, it needs to form a silicon through hole (TSV) that exposes the top metal parts 205 and 203 in the pixel chip 20′ and logic wafer 20, respectively. By forming, for example, the conductive plug 209 in such a TSV, interconnection between the pixel wafer 20′ and the logic wafer 20 can be achieved. The current front-end process is to form an insulating film such as a silicon oxide film on the side wall of a first portion of the TSV after forming the first portion of the TSV in for example the substrate 206, thereby preventing metals from contaminating the elements in the substrate, such as the photodiode 208, during the formation of the conductive plug 209 later.

However, the inventor realized that, in the process of forming a deep trench TSV that reaches the top metal part 203 in the logic wafer 20 by using a method such as plasma etching, the insulating film such as silicon oxide film formed above could not play an adequate protective role. In this case, the plasma in the etching process may penetrate through the insulating film on the side wall of the first portion of the TSV so as to reach, for example, the photodiode 208, thereby producing a charging effect on the photodiode 208, thus affecting the imaging quality of the image sensor. In addition, in some cases, the charging effect of the plasma on the photodiode can lead to white pixel failure, resulting in the failure of the image sensor.

In view of this, the inventor proposes a novel TSV etching protection structure for the stack type BSI image sensor, to reduce a damage to the photodiode during the formation of the TSV.

### First Embodiment

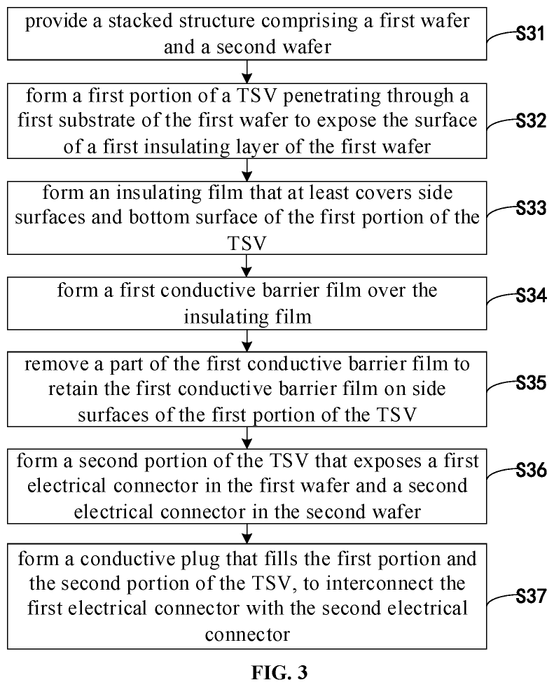

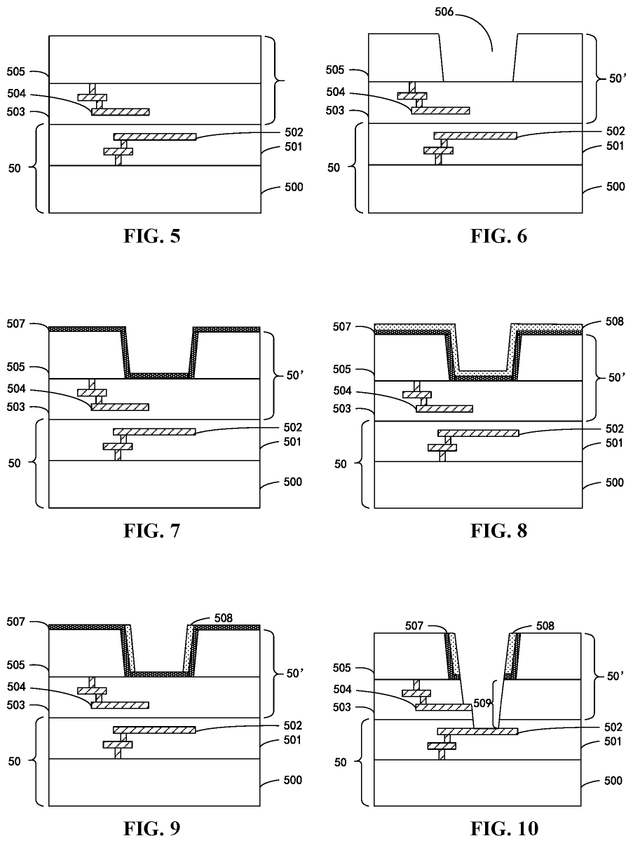

FIG. 3 illustrates a flowchart of steps of manufacturing a semiconductor device according to one or more exemplary embodiments of this disclosure. FIGS. 5-11 are sectional views illustrating main processing steps of a process of manufacturing a semiconductor device according to one or more exemplary embodiments of this disclosure. An example of the method of manufacturing a semiconductor device according to the first embodiment will be described based on the flowchart of the steps in FIG. 3 with reference to the sectional views in FIG. 5 to FIG. 11.

In an embodiment, a stacked structure is provided first, which may include a first wafer and a second wafer (step S31 in FIG. 3). In an example, as shown in FIG. 5, the stacked structure comprises a logic wafer (second wafer) 50 and a pixel wafer (first wafer) 50′.

The logic wafer 50 includes a substrate 500 (second substrate), an insulating layer 501 (second insulating layer) and a top metal part 502 (second electrical connector) formed in the insulating layer 501. In the substrate 500, in addition to the processing circuit for the image sensor, other elements such as capacitors, resistors, memory units, analog devices, filters, transceivers can also be included. In the figures, the description of these elements and circuits is omitted. The material of the substrate 500 is not limited to monocrystalline silicon, but various changes can be made, and other semiconductor materials, such as silicon carbide (SiC), can be used. In addition, a SOI (silicon on the insulator) substrate in which a semiconductor layer for forming the elements can be disposed over an insulating layer can be used as the substrate 500.

The insulating layer 501 can be disposed on the substrate 500, which for example is a combination of interlayer insulating films and lining films that electrically isolate multiple wiring layers from each other, and the top metal part 502 is arranged in the insulating layer 501, to be coupled electrically to the elements and integrated circuits formed in the substrate 500 through a multilayer conductive plug and a multilayer wiring located as a stacked metal part.

The pixel wafer 50′ includes a substrate 505 (first substrate), an insulating layer 503 (first insulating layer) and a top metal part 504 (first electrical connector) formed in the insulating layer 503. In the substrate 505, photodiodes can be included. In addition, the substrate 505 can also include pixel circuits (such as transfer transistors, etc.). In the figures, the description of these elements and circuits is omitted. The material of the substrate 505 is not limited to monocrystalline silicon, but various changes can be made, and other semiconductor materials, such as silicon carbide (SiC), can be used. In addition, a SOI (silicon on the insulator) substrate in which a semiconductor layer for forming the elements can be disposed over an insulating layer can be used as the substrate 505. After forming the photodiode and/or pixel circuit and the corresponding metal interconnection on the front side of the substrate 505, the back side (a side opposite to the insulating layer 503) of the substrate 505 can be thinned to a suitable position for later treatment.

The insulating layer 503 can be disposed over the substrate 505, which for example is a combination of interlayer insulating films and lining films that electrically isolate multiple wiring layers from each other. The top metal part 504 is arranged in the insulating layer 503, to be coupled electrically to the photodiodes and pixel circuits formed in the substrate 505 through a multilayer conductive plug and a multilayer wiring located below it as a stacked metal part. In the stacked structure, the pixel wafer 50′ can be bonded to the logic wafer 50 in such a way that the insulating layer 503 faces the insulating layer 501. The insulating layer 503 of the pixel wafer 50′ can be directly bonded to the insulating layer 501 of the logic wafer 50, or the insulating layer 503 of the pixel wafer 50′ can be bonded to the insulating layer 501 of the logic wafer 500 with a bonding layer.

Next, a first TSV 506 (a first portion of the TSV) penetrating through the substrate 505 to expose a part of the surface of the insulating layer 503 is formed (step S32 in FIG. 3).

As shown in FIG. 6, a resist film (not shown) is formed on the back side (a side opposite to the insulating layer 503) of the substrate 505 of the wafer 50′, and then the resist film is patterned by a lithography process, such that the patterned resist film exposes the surface of the substrate 505 in an region overlapping at least part of the top metal part 504 and at least part of the top metal part 502. Then, through an etching step (ET1), and by using an appropriate etching condition, the substrate 505 exposed by the patterned resist film is removed through the thickness of the substrate 505, thus the first TSV 506 reaching a surface of the insulating layer 503 is formed.

Next, an insulating film 507 that at least covers the side surfaces and the bottom surface of the first TSV 506 is formed (step S33 in FIG. 3).

As shown in FIG. 7, the insulating film 507 is formed on a side of the substrate 505 opposite to the insulating film 503 by means of a method such as chemical vapor deposition (CVD). The insulating film 507 for example can be an oxide film of silicon (for example, silicon oxide film) or a nitride film of silicon (for example, silicon nitride film). The insulating film 507 covers the side surfaces and the bottom surface of the first TSV 506 and also covers the surface of the substrate 505. The insulating film 506 is configured to protect the photodiodes in the substrate 505 from being contaminated by metal in subsequent processes.

Next, a conductive barrier film 508 (the first conductive barrier film) is formed over the insulating film 507 (step S34 in FIG. 3).

As shown in FIG. 8, the conductive barrier film 508 is formed over the insulating film 507 in a conformal manner by means of sputtering method and so on. The conductive barrier film 508 is formed over the sidewalls of the first TSV 506 to prevent the photodiodes in the substrate 505 from being charged by the plasma during the subsequent etching process, thus preventing a white pixel failure in the photodiodes. In an example, preferably, the conductive barrier film 508 is formed of the same material as a conductive barrier film used in forming a conductive plug in the subsequent process, so that the resistance of the conductive plug will not change significantly. In an example, a laminated film containing a tantalum (Ta) film and a tantalum nitride (TaN) film located above the Ta film is deposited as the conductive barrier film. In other words, the conductive barrier film 508 can be a Ta/TaN film.

Next, a part of the conductive barrier film 508 is removed to retain the conductive barrier film 508 on the side surfaces of the first TSV 506 (step S35 in FIG. 3).

As shown in FIG. 9, in an example, directly through a blanket etch instead of through the lithography process, the conductive barrier film 508 at the bottom surface of the first TSV 506 and on the substrate 505 is removed, and the the conductive barrier film 508 on the side surfaces of the first TSV 506 is retained.

Next, a second TSV 509 (a second portion of the TSV) that exposes the top metal part 504 and the top metal part 502 is formed (step S36 in FIG. 3).

As shown in FIG. 10, through the plasma blanket etch, and by using a suitable plasma gas, the insulation film 507 that is not covered by the conductive barrier film 508 at the bottom surface of the first TSV 506 and the insulating film 507 on the substrate 505 are removed. Subsequently, the plasma blanket etch is continued, and the insulating layer 503 is penetrated and a part of the insulating layer 501 is removed, thus the second TSV 509 that exposes at least part of the top metal part 504 and at least part of the top metal part 502 is formed. Although in FIG. 10, the thickness of the substrate 505 does not change during the formation of the second TSV 509, a depth of which is the entire thickness of the insulating layer 503 and the thickness of a part of the insulating layer 501, those skilled in the art would understand that, after thinning the back side of the substrate 505, the substrate 505 still has a sufficient thickness or the substrate 505 still has a protective film such as a silicon oxide film, which is thick enough to protect the photodiode in the substrate 505 during the etching process. In order to simplify the figures, this change is not reflected in FIG. 10 and the subsequent figures.

Next, a conductive plug 511 that fills the first TSV 506 and the second TSV 509 to interconnect the top metal parts 204 and 502 is formed (step S37 in FIG. 3).

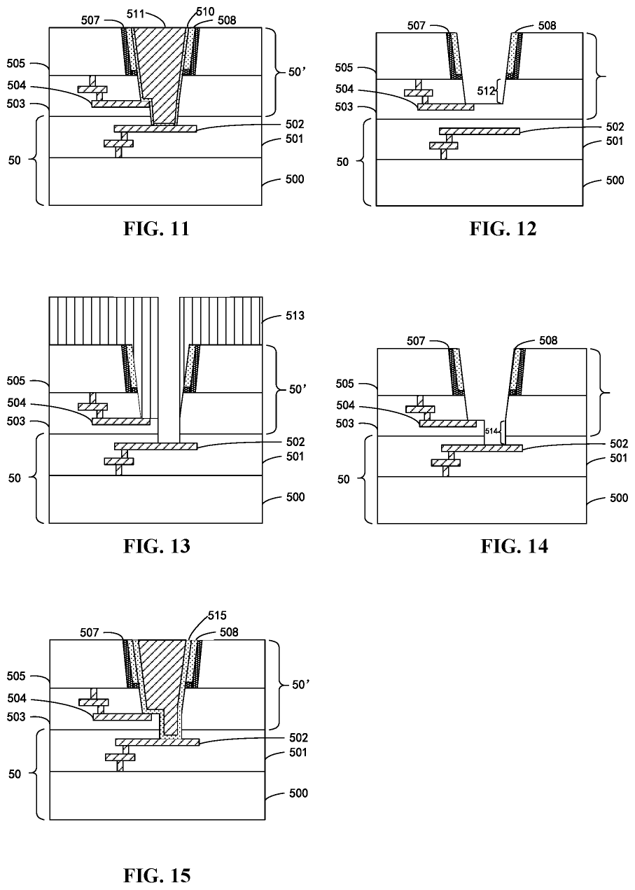

As shown in FIG. 11, first, by means of a sputtering method, etc., for example a laminated film containing a tantalum (Ta) film and a tantalum nitride (TaN) film located above the Ta film on a side of the substrate 505 opposite to the insulating layer 503 is deposited, as a conductive barrier film 510 which covers the substrate 505, and the side surfaces and the bottom surface of the first TSV 506 and the second TSV 509 covered by the insulating film 507 and the conductive barrier film 508. Subsequently, a thin copper film as a copper seed film (not shown) is deposited above the barrier film 510 by the sputtering method, etc., and a copper film is deposited above the copper seed film by an electrolytic plating method (single damascene method). Subsequently, for example, through the CMP method etc., the unnecessary conductive barrier film 510, the copper seed film and the copper film above the substrate 505 is removed, thereby forming the conductive plug 511.

In an embodiment, the processes in FIGS. 9 and 10 can be performed in the same blanket etching process. During the blanket etching process, it may be required to change the etchant to respectively etch the conductive barrier film 508 as well as the insulating film 507, the insulating layer 503 and the insulating layer 501. Therefore, the whole TSV can be formed by a lithography process and two etching processes.

The semiconductor device according to the first embodiment is manufactured in this way. In the semiconductor device formed by the above processing steps, a protective layer such as Ta/TaN is formed over the side surfaces of the first TSV 506 before the blanket etching process, thus reducing the charging effect of plasma on the photodiode in the substrate 505 during the blanket etching process, thereby preventing the occurrence of white pixel failures in the photodiode.

In addition, as can be seen from the above processing steps, in an embodiment, a thickness of the conductive barrier film (including the conductive barrier films 508 and 510) in the first TSV 506 in a direction perpendicular to the side surfaces is thicker than a thickness of the conductive barrier film 510 in the second TSV 509 in the direction perpendicular to the side surfaces. As can be seen from the above processing steps, the conductive barrier films 508 and 510 both are, for example, laminated layers containing Ta/TaN films. It follows that, the number of the conductive barrier layers (Ta/TaN/Ta/TaN layers) of the conductive barrier film (including the conductive barrier films 508 and 510) in the first TSV 506 is more than the number of the conductive barrier layers (Ta/TaN layers) of the conductive barrier film 510 in the second TSV 509.

### Second Embodiment

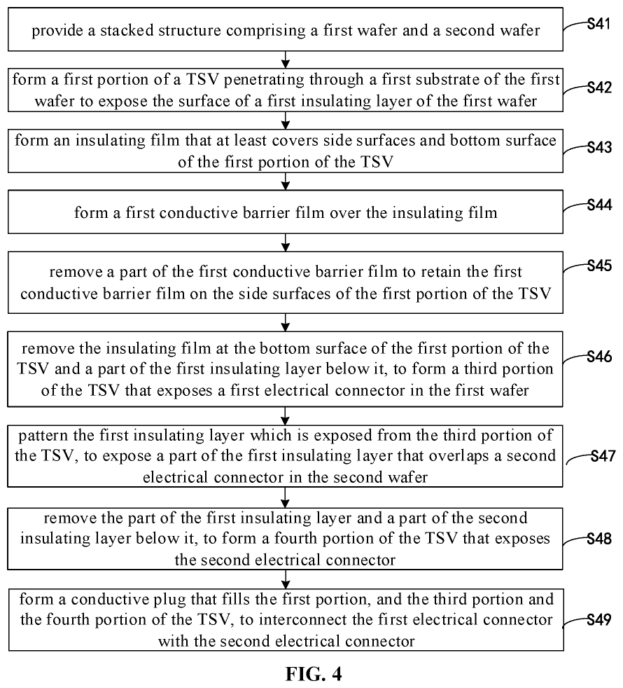

FIG. 4 illustrates a flowchart of steps of manufacturing a semiconductor device according to one or more exemplary embodiments of this disclosure. FIGS. 12-15 are sectional views illustrating main processing steps of a process of manufacturing a semiconductor device according to one or more exemplary embodiments of this disclosure.

An example of the method of manufacturing a semiconductor device according to the second embodiment will be described based on the flowchart of the steps in FIG. 4 with reference to the sectional views in FIG. 12 to FIG. 15.

In this embodiment, the steps S41-S45 in FIG. 4 are similar to the steps S31-35 in FIG. 3 in the first embodiment (corresponding to the sectional views in FIGS. 5-9). Therefore, the processing steps and the corresponding sectional views of the main parts of the semiconductor device are not repeated here.

In the second embodiment, after the step of FIG. 9, the insulating film 507 at the bottom surface of the first TSV 506 and a part of the insulating layer 503 below is removed, to form a third TSV 512 that exposes the top metal part 504 (step S46 in FIG. 4).

As shown in FIG. 12, after the step of FIG. 9, through for example the plasma blanket etching step (ET2), and by using a suitable plasma gas, the insulating film 507 which is not covered by the conductive barrier film 508 at the bottom surface of the first TSV 506 and the insulating film 507 on the substrate 505 are removed. Subsequently, for example the plasma blanket etching process is continued, thereby forming the third TSV 512 that exposes the at least part of the top metal part 504.

Next, the insulating layer 503 which is exposed from the third TSV 512 is patterned, to expose a part of the insulating layer 503 that overlaps the top metal part 502 (step S47 in FIG. 4).

As shown in FIG. 13, a resist pattern 513 is formed by, for example, the lithography process, so that the resist pattern 513 exposes the part of the insulating layer 503 that overlaps the top metal part 502. Preferably, the resist pattern 513 exposes a part of the insulating layer 503 at the bottom surface of the third TSV 512 but covers the insulating layer 503 at the side surfaces of the third TSV 512 and the top metal part 504 at the bottom surface of the third TSV, so as to prevent the top metal part 504 from being damaged during the subsequent etching process.

Subsequently, the exposed part of the insulating layer 503 and a part of the insulating layer 501 below are removed, thereby forming a fourth TSV 514 that exposes the top metal part 502 (step S48 in FIG. 4).

As shown in FIG. 13 and FIG. 14, through steps such as plasma etching (ET3), the insulating layer 503 exposed by the resist pattern 513 and a part of the insulating layer 501 below are removed, thus forming the fourth TSV 514. Then, as shown in FIG. 14, the resist pattern 513 is removed by a method such as wet stripping.

Next, a conductive plug 516 that fills the first TSV 506 and the third TSV 512 and the fourth TSV 514 is formed, to interconnect the top metal parts 504 and 502 (step S49 in FIG. 4).

As shown in FIG. 15, first, by means of a sputtering method, etc., for example a Ta/TaN laminated film containing a tantalum (Ta) film and a tantalum nitride (TaN) film located above the Ta film is deposited on a side of the substrate 505 opposite to the insulating layer 503, as a conductive barrier film 515 which covers the substrate 505, the side surfaces of the first TSV 506 covered by the insulating film 507 and the conductive barrier film 508, the side surfaces of the third TSV 512, and the side surfaces and the bottom surface of the fourth TSV 514. Subsequently, a thin copper film as a copper seed film (not shown) is deposited above the conductive barrier film 515 by such as sputtering method, and a copper film is deposited above the copper seed film by an electrolytic plating method (single damascene method). Subsequently, for example, through the CMP method etc., the unnecessary conductive barrier film 515, the copper seed film and the copper film above the substrate 505 are removed, thereby forming the conductive plug 516.

As can be learned from the above steps, the entire TSV can be formed through two lithography processes and three etching processes (ET1, ET2 and ET3).

The semiconductor device according to the second embodiment is manufactured in this way. In the semiconductor device formed by the above processing steps, a protective layer such as Ta/TaN is formed on the side surfaces of the first TSV 506 before the ET2 blanket etching process, thus reducing the charging effect of plasma on the photodiode in the substrate 505 during the blanket etching process, thereby preventing the occurrence of white pixel failures in the photodiode. In addition, by using the lithography process to form the fourth TSV 514, the top metal part 504 can be protected from being damaged by the subsequent plasma, and the shape of the fourth TSV 514 can be defined as needed.

In addition, as can be seen from the above processing steps, in an embodiment, a thickness of the conductive barrier film (including the conductive barrier films 508 and 515) in the first TSV 506 in a direction perpendicular to the side surfaces is thicker than a thickness of the conductive barrier film 515 in the third TSV 512 and the fourth TSV 514 in the direction perpendicular to the side surfaces. Further, as can be seen from the above processing steps, the conductive barrier films 508 and 515 both are, for example, Ta/TaN laminated layers containing Ta films and TaN films. It follows that, the number of the conductive barrier layers (Ta/TaN/Ta/TaN layers) of the conductive barrier film (including the conductive barrier films 508 and 515) in the first TSV 506 is more than the number of the conductive barrier layers (Ta/TaN layers) of the conductive barrier film 515 in the third TSV 512 and the fourth TSV 514.

The semiconductor device according to the above embodiments can be used in mobile phones, computers, robots, surveillance, medical, automotive and many other fields. In addition to the components mentioned above, the semiconductor device can also include components known in the art, such as central processing units (CPU), memories (non-volatile memory and volatile memory), and so on.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or element tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or elements, but do not preclude the presence or addition of one or more other features, integers, steps, operations, elements, elements, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

It should be further understood that, the present disclosure further proposes the following items.

In one embodiment, the first wafer is a pixel wafer, and the pixel wafer comprises a stacked metal part and the first electrical connector is a top metal part in the stacked metal part.

In one embodiment, the second wafer is a logic wafer, and the logic wafer comprises a stacked metal part and the second electrical connector is a top metal part in the stacked metal part.

What is claimed is:

1. A method of manufacturing a semiconductor device, comprising the steps of:
providing a stacked structure comprising:
a first wafer that includes a first substrate and a first insulating layer over the first substrate and a first electrical connector in the first insulating layer;
a second wafer that includes a second substrate and a second insulating layer over the second substrate and a second electrical connector in the second insulating layer, wherein the first wafer is bonded to the second wafer in such a way that the first insulating layer faces the second insulating layer;
forming a first portion of a silicon through hole TSV from a side of the first substrate opposite to the first insulating layer, wherein the first portion of the TSV overlaps at least part of the first electrical connector and at least part of the second electrical connector and penetrates through the first substrate and exposes a part of a surface of the first insulating layer;
forming an insulating film that at least covers side surfaces and a bottom surface of the first portion of the TSV;
forming a first conductive barrier film over the insulating film;
removing a part of the first conductive barrier film, to retain the first conductive barrier film on the side surfaces of the first portion of the TSV;
removing the insulating film at the bottom surface of the first portion of the TSV and the part of the first insulating layer and the second insulating layer below it, thereby forming a second portion of the TSV that exposes the at least part of the first electrical connector and the at least part of the second electrical connector;
forming a conductive plug that fills the first portion and the second portion of the TSV, to interconnect the first electrical connector with the second electrical connector.

2. The method according to claim 1, the step of forming the second portion of the TSV comprising the steps of:
removing the insulating film at the bottom surface of the first portion of the TSV and the part of the first insulating layer below it, to form a third portion of the TSV that exposes the at least part of the first electrical connector;
patterning the first insulating layer which is exposed by the third portion of the TSV, to expose the part of the first insulating layer that overlaps the at least part of the second electrical connector;
removing the part of the first insulating layer and a part of the second insulating layer below it, to form a fourth portion of the TSV that exposes the at least part of the second electrical connector;
wherein the third portion of the TSV and the fourth portion of the TSV form the second portion of the TSV.

3. The method according to claim 1, after the step of forming the second portion of the TSV and before the step of forming the conductive plug, further comprising the step of:
forming a second conductive barrier film that covers the first conductive barrier film in the first portion of the TSV and covers the side surfaces and the bottom surface of the second portion of the TSV in the second portion of the TSV.

4. The method according to claim 1, wherein the first wafer is a pixel wafer, and the pixel wafer comprises a stacked metal part and the first electrical connector is a top metal part in the stacked metal part.

5. The method according to claim 1, wherein the second wafer is a logic wafer, and the logic wafer comprises a stacked metal part and the second electrical connector is a top metal part in the stacked metal part.

6. The method according to claim 1, wherein the step of forming the second portion of the TSV is performed by a plasma etching process.

7. The method according to claim 1, wherein the insulating film is an oxide film of silicon or a nitride film of silicon.

8. The method according to claim 3, wherein the first conductive barrier film and the second conductive barrier film are formed of the same material.

9. The method according to claim 1, wherein the first conductive barrier film comprises a Ta/TaN film.

10. A semiconductor device comprising:
a first wafer that includes a first substrate and a first insulating layer over the first substrate and a first electrical connector in the first insulating layer;
a second wafer that includes a second substrate and a second insulating layer over the second substrate and a second electrical connector in the second insulating layer, wherein the first wafer is bonded to the second wafer in such a way that the first insulating layer faces the second insulating layer;
a silicon through hole TSV comprising a first portion and a second portion, wherein the first portion of the TSV overlaps at least part of the first electrical connector and at least part of the second electrical connector and penetrates through the first substrate and exposes a part of a surface of the first insulating layer; wherein the second portion is in part of the first insulating layer and the second insulating layer to expose the at least part of the first electrical connector and the at least part of the second electrical connector;
a conductive barrier film that covers side surfaces and a bottom surface of the TSV, wherein a thickness of the conductive barrier film in the first portion of the TSV in a direction perpendicular to the side surfaces is greater than a thickness of the conductive barrier film in the second portion of the TSV in the direction perpendicular to the side surfaces;
a conductive plug that fills the TSV covered by the conductive barrier film and interconnects the first electrical connector with the second electrical connector.

11. The semiconductor device according to claim 10, wherein the second portion comprises a third portion of the TSV that is in part of the first insulating layer and exposes the at least part of the first electrical connector, and a fourth portion of the TSV that is below the third portion of the TSV and exposes the at least part of the second electrical connector.

12. The semiconductor device according to claim 10, further comprising an insulating film between the side surfaces of the TSV and the conductive barrier film, in the first portion of the TSV.

13. The semiconductor device according to claim 12, wherein the insulating film is an oxide film of silicon or a nitride film of silicon.

14. The semiconductor device according to claim 10, wherein the conductive barrier film in the first portion of the TSV comprises a Ta/TaN/Ta/TaN film.

15. A semiconductor device comprising:
a first wafer that includes a first substrate and a first insulating layer over the first substrate and a first electrical connector in the first insulating layer;
a second wafer that includes a second substrate and a second insulating layer over the second substrate and a second electrical connector in the second insulating layer, wherein the first wafer is bonded to the second wafer in such a way that the first insulating layer faces the second insulating layer;
a silicon through hole TSV comprising a first portion and a second portion, wherein the first portion of the TSV overlaps at least part of the first electrical connector and at least part of the second electrical connector and penetrates through the first substrate and exposes a part of a surface of the first insulating layer; wherein the second portion is in part of the first insulating layer and the second insulating layer to expose the at least part of the first electrical connector and the at least part of the second electrical connector;
a conductive barrier film that covers side surfaces and a bottom surface of the TSV and comprises one or more conductive barrier layers, wherein the number of the conductive barrier layers of the conductive barrier film in the first portion of the TSV is more than the number of the conductive barrier layers of the conductive barrier film in the second portion of the TSV;
a conductive plug that fills the TSV covered by the conductive barrier film and interconnects the first electrical connector with the second electrical connector.

16. The semiconductor device according to claim 15, wherein the second portion comprises a third portion of the TSV that is in part of the insulating layer and exposes the at least part of the first electrical connector, and a fourth portion of the TSV that is below the third portion of the TSV and exposes the at least part of the second electrical connector.

17. The semiconductor device according to claim 15, wherein a thickness of the conductive barrier film in the first portion of the TSV in a direction perpendicular to the side surfaces is greater than a thickness of the conductive barrier film in the second portion of the TSV in the direction perpendicular to the side surfaces.

18. The semiconductor device according to claim 15, further comprising an insulating film between the side surfaces of the TSV and the conductive barrier film, in the first portion of the TSV.

19. The semiconductor device according to claim 18, wherein the insulating film is an oxide film of silicon or a nitride film of silicon.

20. The semiconductor device according to claim 15, wherein the conductive barrier film in the first portion of the TSV comprises a Ta/TaN/Ta/TaN film.
